(19) United States
(12) Patent Application Publication
(10) Pub. No.: US 2019/0215987 A1
(43) Pub. Date: Jul. 11, 2019

(54) WATER-COOLING RADIATOR STRUCTURE

(71) Applicant: ASIA VITAL COMPONENTS CO., LTD., New Taipei City (TW)

(72) Inventor: Wen-Ji Lan, New Taipei City (TW)

(21) Appl. No.: 15/867,702

(22) Filed: Jan. 11, 2018

(51) Int. Cl. H05K 7/20

(52) U.S. Cl. CPC H05K 7/20263; H05K 7/20272; G06F 1/20; H05K 7/20772; H05K 7/20136

(57) ABSTRACT

A water-cooling radiator structure includes a water-cooling radiator unit, which includes a water-receiving plate internally defining a water chamber for a working fluid to flow therethrough. The water-receiving plate has an upper surface and a lower surface, from where heat carried by the working fluid flowing through the water chamber is dissipated into ambient air.

### FIELD OF THE INVENTION

The present invention relates to a heat dissipation structure, and more particularly, to a water-cooling radiator structure.

### BACKGROUND OF THE INVENTION

Many electronic elements in a computer will produce a large quantity of heat when the computer operates. Hence, a good heat dissipation system is a key factor that determines the effectiveness and reliability of a computer. In a computer, the workload of the central processing unit (CPU) and the graphic processing unit (GPU) is higher than any other heat-producing elements in the computer, and accordingly, solutions for dissipating heat produced by the CPU and the GPU are no doubt very important. Particularly, the currently available computer games all include highly exquisite images that require computer-aided design (CAD) software with increasingly enhanced functions to achieve. However, the operation of such CAD software will render the CPU and the GPU into a heavy workload state to produce a huge quantity of heat. Heat accumulated in the computer would result in lowered performance of the CPU and GPU, or, in some worse condition, even result in damages or largely shortened service life of the CPU and GPU.

Different water cooling systems are available in the market for lowering the working temperature of the heat-producing electronic elements. A conventional water cooling system generally includes a water-cooling radiator fluid-communicably connected to a pump and a water block via two water pipes. The water block is in contact with a heat-producing element, such as a CPU. The pump drives a cooling liquid, i.e. a working fluid such as water, from the water block to flow into the water-cooling radiator, so that heat absorbed and carried by the working fluid is transferred to and dissipated from the water-cooling radiator into ambient air. The pump drives the cooling liquid to continuously circulate between the water-cooling radiator and the water block to enable quick removal of heat from the heat-producing electronic element. FIG. 1 shows a conventional water-cooling radiator structure 1, which includes a plurality of radiating fins 11, a plurality of straight flat pipes 12, and two side water tanks 13. The radiating fins 11 are arranged between any two adjacent flat pipes 12 and the two side water tanks 13 are soldered to the radiating fins 11 and two opposite ends of the flat pipes 12, so that the two side water tanks 13, the radiating fins 11 and the straight flat pipes 12 together constitute the water-cooling radiator structure 1. A first one of the two side water tanks 13 is provided with a water inlet 131 and a water outlet 132, which are separately connected to the above-mentioned two water pipes (not shown).

The working fluid flowed into the first side water tank 13 via the water inlet 131 quickly and straightly flows through the straight flat pipes 12 to the second side water tank 13, and then quickly flows back to the first side water tank 13 via the straight flat pipes 12 and leaves the water-cooling radiator structure 1 via the water outlet 132. Therefore, the time period from the entering to the leaving of the heat-carrying working fluid into and from the water-cooling radiator structure 1 is very short and there is not sufficient time for the heated working fluid to exchange heat with the water-cooling radiator structure 1. As a result, the conventional water-cooling radiator structure 1 could not effectively remove the heat from the working fluid flowing therethrough and has the problem of poor heat dissipation efficiency. In addition, the conventional water-cooling radiator structure 1 is an integral structure, which is not adjustable or changeable according to the internal space of an electronic device that uses the water-cooling radiator structure 1. Therefore, to use the water-cooling radiator structure 1 inside an electronic device, such as a computer or a server, the electronic device must have an independent internal space sufficient for installing the water-cooling radiator structure 1.

It is therefore tried by the inventor to develop an improved water-cooling radiator structure to overcome the problems and disadvantages in the prior art water-cooling radiator structure.

### SUMMARY OF THE INVENTION

A primary object of the present invention is to provide a water-cooling radiator structure that has good heat removal performance.

Another object of the present invention is to provide a water-cooling radiator structure that includes a water-receiving plate, in which a pump can be optionally provided.

A further object of the present invention is to provide a water-cooling radiator structure that includes a water-cooling radiator unit consisting of a plurality of water-receiving plates, which are fluid-communicable with one another via a communicating element portion. The water-receiving plates can be stacked in a vertically closely spaced manner or be distributed in a distantly spaced manner, depending on the usage environment in which the water-cooling radiator unit is arranged.

To achieve the above and other objects, the water-cooling radiator structure according to a preferred embodiment of the present invention includes a water-cooling radiator unit, which consists of a water-receiving plate internally defining a water chamber for a working fluid to flow therethrough. The water-receiving plate has an upper surface and a lower surface, from where heat carried by the working fluid flowing through the water chamber is dissipated into ambient air.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a prior art water-cooling radiator structure;

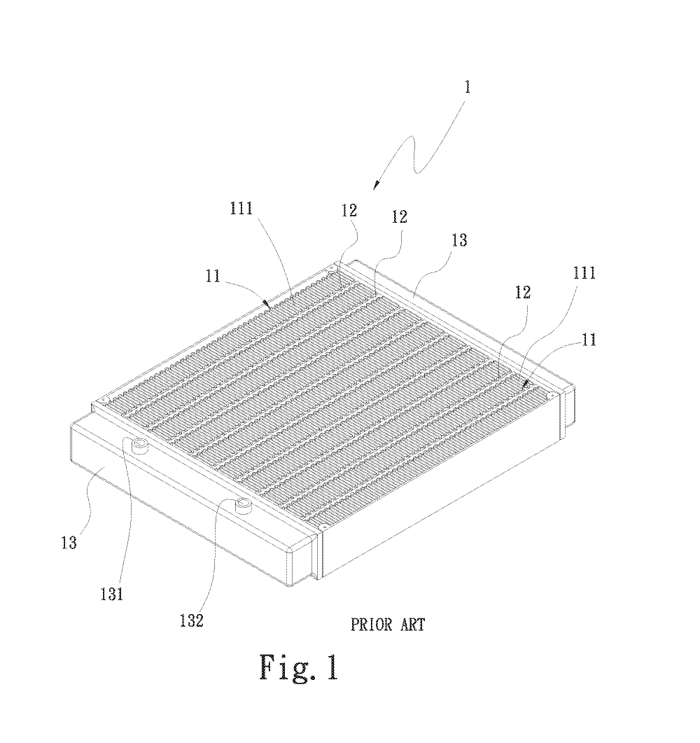

FIG. 2A is an exploded perspective view of a water-cooling radiator structure according to a first embodiment of the present invention;

FIG. 2B is an exploded perspective view of a first variant of the first embodiment of the present invention, characterized by including a flow passage;

FIG. 2C is an exploded perspective view of a second variant of the first embodiment of the present invention, characterized by including a plurality of radiating fin assemblies;

FIG. 3A is an exploded perspective view of a third variant of the first embodiment of the present invention, characterized by having a water block unit connected thereto;

FIG. 3B is an assembled view of FIG. 3A;

FIG. 3C is an exploded perspective view of a fourth variant of the first embodiment of the present invention, which is a combination of the second and third variants of FIGS. 2c and 3A and further includes a protection unit and at least one fan;

FIG. 3D is an assembled view of FIG. 3C;

FIG. 4A is an exploded perspective view of a water-cooling radiator structure according to a second embodiment of the present invention;

FIG. 4B is an assembled sectional view of FIG. 4A;

FIG. 4C is an exploded perspective view of a first variant of the second embodiment of the present invention, characterized by including a first flow passage;

FIG. 4D is an exploded perspective view of a second variant of the second embodiment of the present invention, characterized by including a first and a second flow passage;

FIG. 5 is an exploded perspective view of a third variant of the second embodiment of the present invention, characterized by including a plurality of radiating fin assemblies;

FIG. 6A is an exploded perspective view of a fourth variant of the second embodiment of the present invention, characterized by having a water block unit connected thereto;

FIG. 6B is an assembled perspective view of a fifth variant of the second embodiment of the present invention, characterized by including a plurality of radiating fin assemblies and having a water block unit connected thereto;

FIG. 6C is an exploded perspective view of a sixth variant of the second embodiment of the present invention, which is a combination of the fifth variant of FIG. 6B and a protection unit and at least one fan; and

FIG. 7 is an assembled perspective view of a seventh variant of the second embodiment of the present invention, characterized by including a plurality of distantly spaced water-receiving plates.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

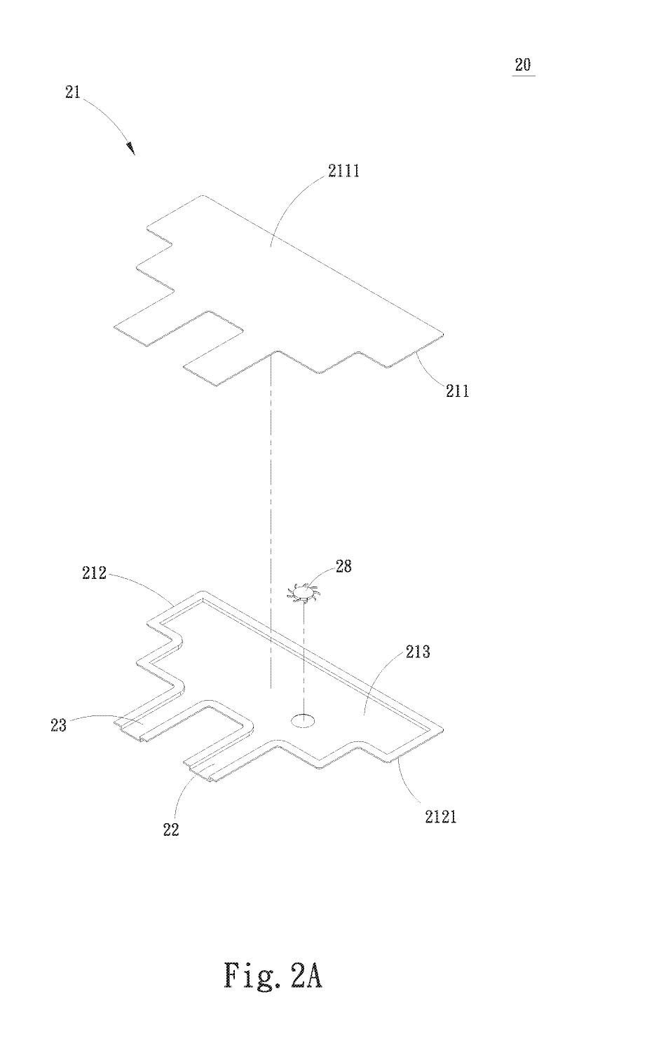

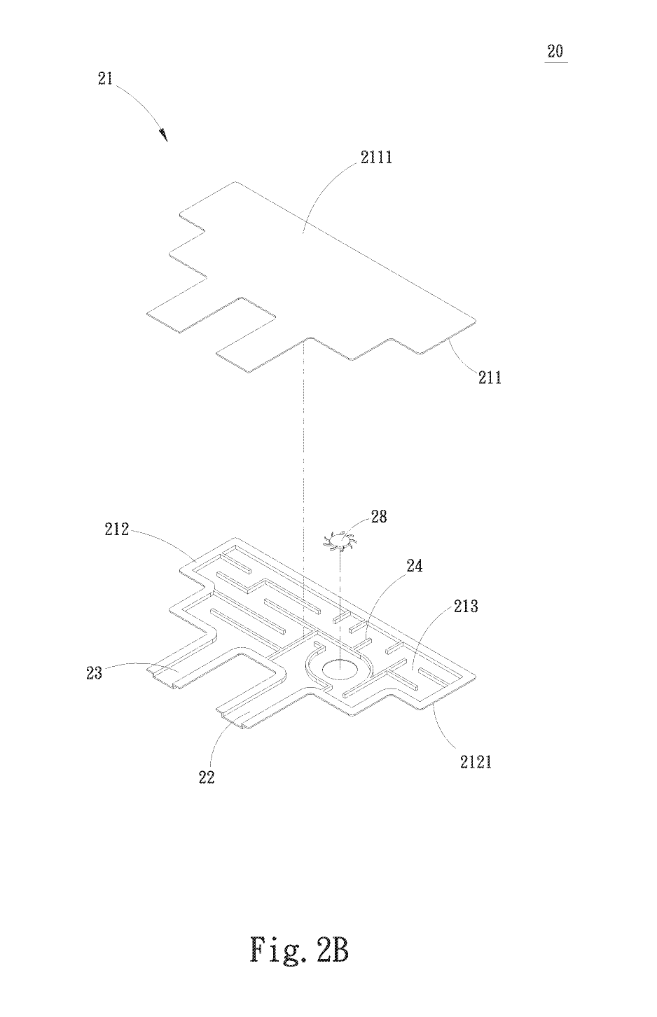

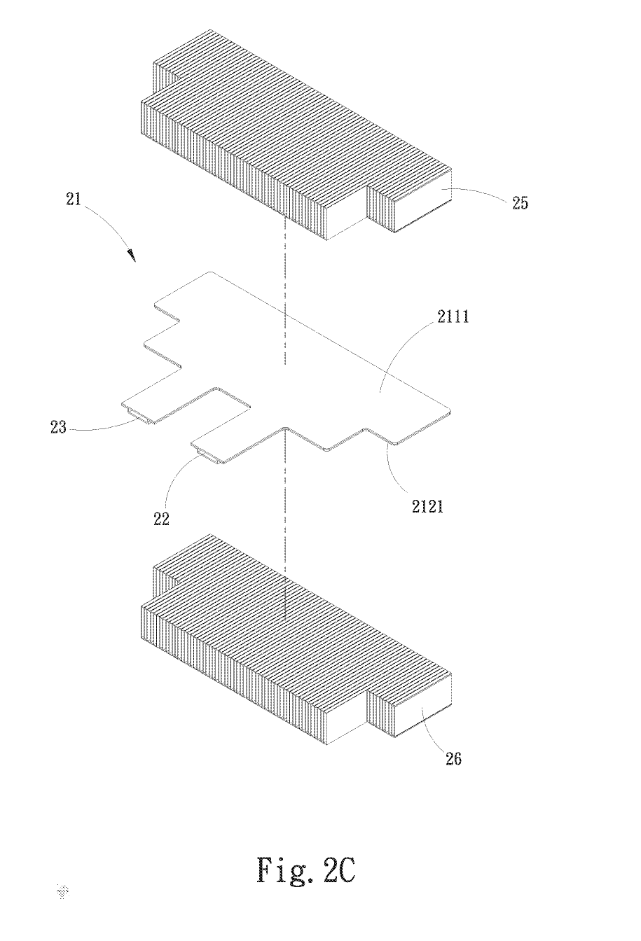

Please refer to FIGS. 2A and 2B, which are exploded perspective views of a water-cooling radiator structure according to a first embodiment of the present invention and a first variant thereof, respectively. As shown, in the first embodiment, the water-cooling radiator structure includes a water-cooling radiator unit 20. The water-cooling radiator unit 20 includes a water-receiving plate 21, which is formed of a top plate member 211 and a bottom plate member 212, such that a water chamber 213 is defined in between the top plate member 211 and the bottom plate member 212. The top and the bottom plate member 211, 212 are correspondingly provided with two outward extended portions each, such that a water inlet 22 and a water outlet 23 are formed between the extended portions of the top and bottom plate members 211, 212 when they are closed to each other to form the water-receiving plate 21. The water inlet 22 and the water outlet 23 are communicable with the water chamber 213. An outer side of the top plate member 211 is defined as an upper surface 2111, and an outer side of the bottom plate member 212 is defined as a lower surface 2121. A working fluid, such as pure water, that has absorbed heat outside the water-receiving plate 21, flows into the water chamber 213 via the water inlet 22 and then flows through the water chamber 213 to leave there via the water outlet 23. When the working fluid flows in through the water chamber 213, heat absorbed and carried by the working fluid is transferred to the upper surface 2111 of the top plate member 211 and to the lower surface 2121 of the bottom plate member 212, from where the heat is dissipated into ambient air. In the first embodiment shown in FIG. 2A, the water chamber 213 is a hollow chamber. However, as shown in FIG. 2B, in the first variant of the first embodiment, the water chamber 213 is internally provided with a winding flow passage 24, two ends of which are separately communicable with the water inlet 22 and the water outlet 23. In FIG. 2B, the illustrated flow passage 24 is formed by providing a plurality of partitioning ribs in the water chamber 213. However, in an operable embodiment, the flow passage can be otherwise formed by providing one or a plurality of grooves in the water chamber 213. The flow passage 24 and the water-receiving plate 21 can be two individual members or can be integrally formed with each other. The flow passage 24 can be connected to or formed on one side of the top plate member 211 facing toward the water chamber 213, or be connected to or formed on one side of the bottom plate member 212 facing toward the water chamber 213. The working fluid flowed into the water chamber 213 flows along the flow passage 24 toward the water outlet 23. Therefore, the flow passage 24 functions as a guide path for the working fluid.

A pump 28 can be optionally arranged inside or outside the water-receiving plate 21. In the illustrated first embodiment and the first variant thereof, the pump 28 is arranged in the water chamber 213. The pump 28 arranged in the water chamber 213 can be disposed near the water inlet 22 or the water outlet 23. In an operable embodiment, the pump 28 can be disposed at the water inlet 22 or the water outlet 23. The pump 28 can include, for example, an impeller and a driving motor for driving the impeller to rotate and accordingly, drive the working fluid to flow. The driving motor can be, for example, a submersible motor or a waterproof motor.

FIG. 2C is an exploded perspective view of a second variant of the first embodiment of the present invention. In the second variant of the first embodiment, the water-cooling radiator unit 20 further includes a first radiating fin assembly 25 connected to the upper surface 2111 of the water-receiving plate 21, and/or a second radiating fin assembly 26 connected to the lower surface 2121 of the water-receiving plate 21. The first and the second radiating fin assembly 25, 26 respectively include a plurality of radiating fins. Heat transferred to the upper surface 2111 and the lower surface 2121 is dissipated from the first and the second radiating fin assembly 25, 26 into ambient air.

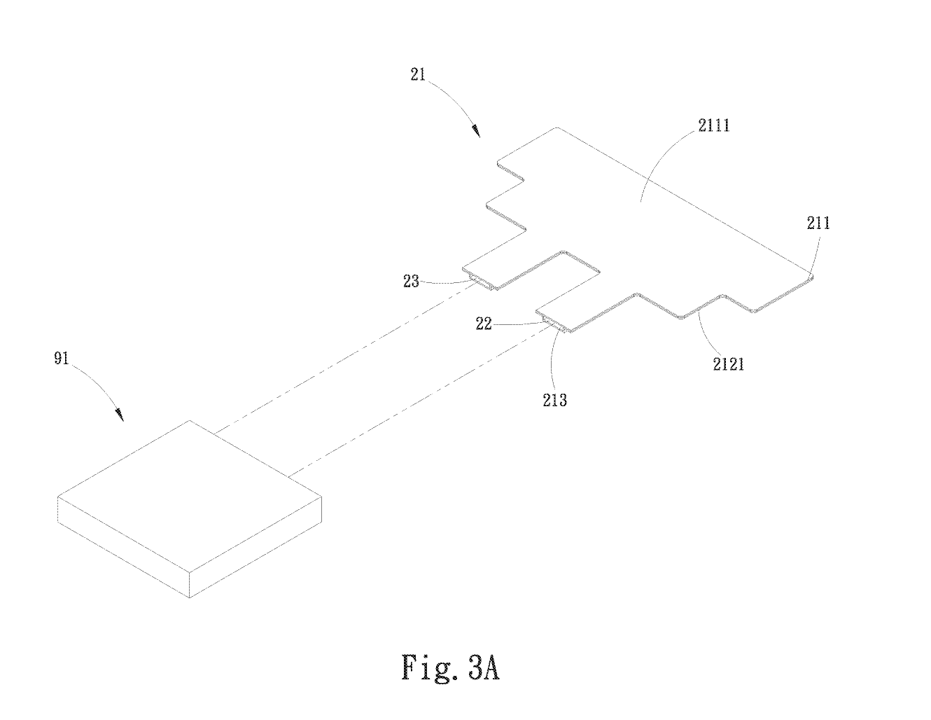

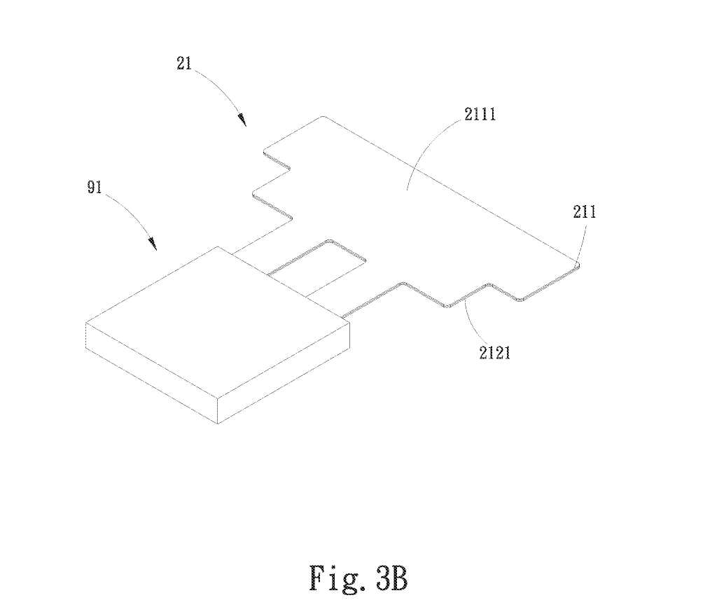

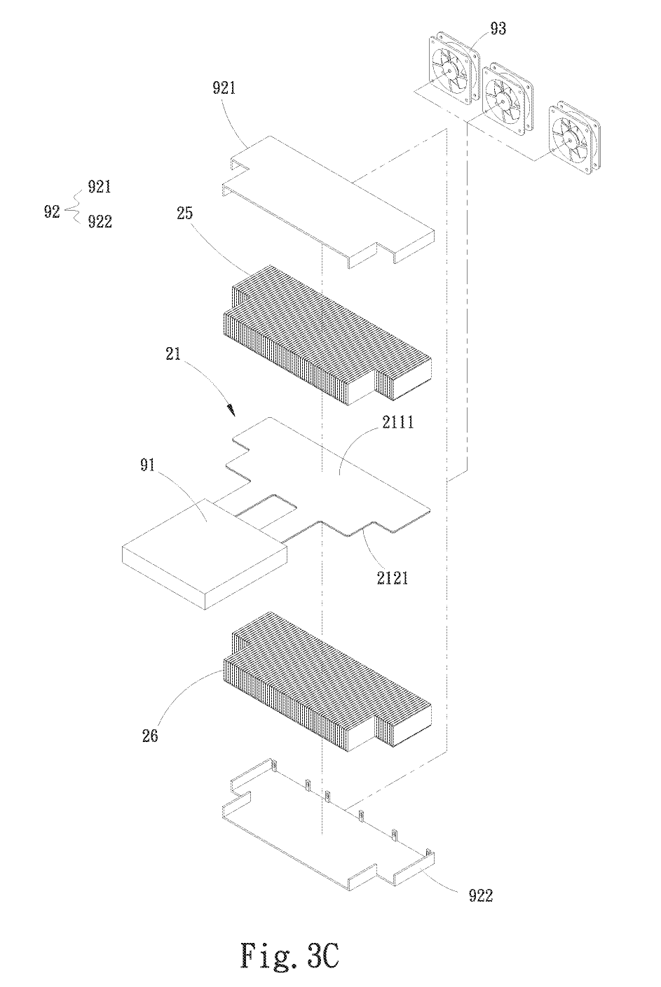

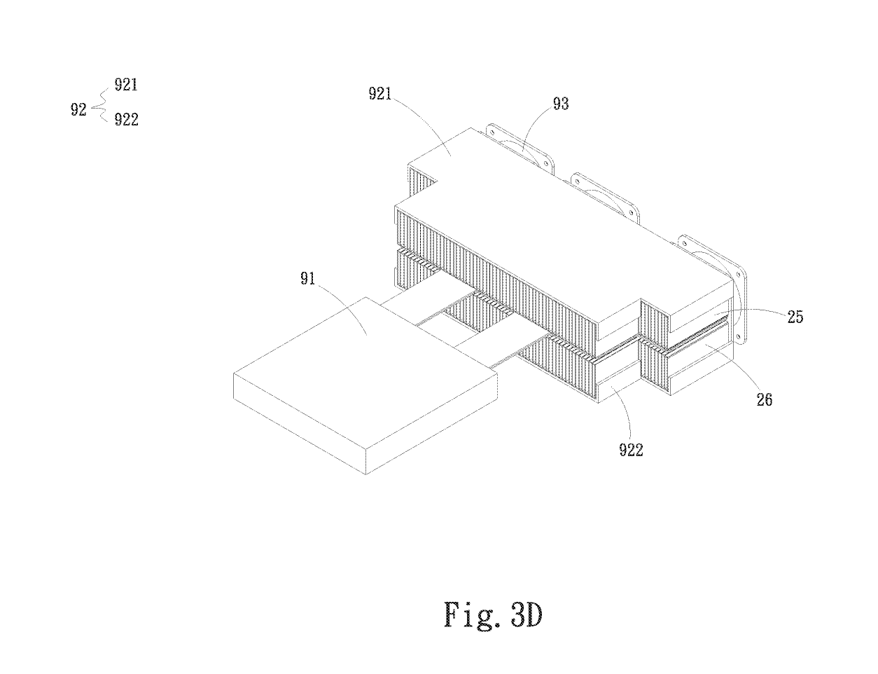

FIGS. 3A and 3B are exploded and assembled perspective views, respectively, of a third variant of the first embodiment of the present invention. In the third variant of the first embodiment, the water inlet 22 and the water outlet 23 of the water-receiving plate 21 are fluid-communicably connected to a water block unit 91. The water block unit 91 has an outer surface in contact with at least one heat-producing element. The water block unit 91 is communicable with the water inlet 22 and the water outlet 23. The working fluid flowing out of the water-receiving plate 21 via the water outlet 23 flows into the water block unit 91. The working fluid in the water block unit 91 absorbs heat through heat exchange with the heat-producing element, and the heated working fluid flows into the water chamber 213 of the water-receiving plate 21 via the water inlet 22, so that heat carried by the working fluid is radiated into ambient air from the water-receiving plate 21.

FIGS. 3C and 3D are exploded and assembled perspective views, respectively, of a fourth variant of the first embodiment of the present invention. The fourth variant of the first embodiment is a combination of the second and the third variant of the first embodiment and further includes a protection unit 92, which can be in the form of a set of covers or a set of frames. In the illustrated fourth variant, the protection unit 92 includes a first protection part 921 and a second protection part 922, which protectively cover the first radiating fin assembly 25, the second radiating fin assembly 26 and the water-receiving plate 21 from a top side and a bottom side of the water-cooling radiator unit 20, protecting the first radiating fin assembly 25, the second radiating fin assembly 26 and the water-receiving plate 21 against damages. Further, at least one fan 93 can be optionally connected to the protection unit 92 with a fan outlet of the fan 93 facing toward the first and the second radiating fin assembly 25, 26 and the water-receiving plate 21, so that airflow produced by the fan 93 flows to the first and the second radiating fin assembly 25, 26 and the water-receiving plate 21 to enable enhanced heat dissipation effect.

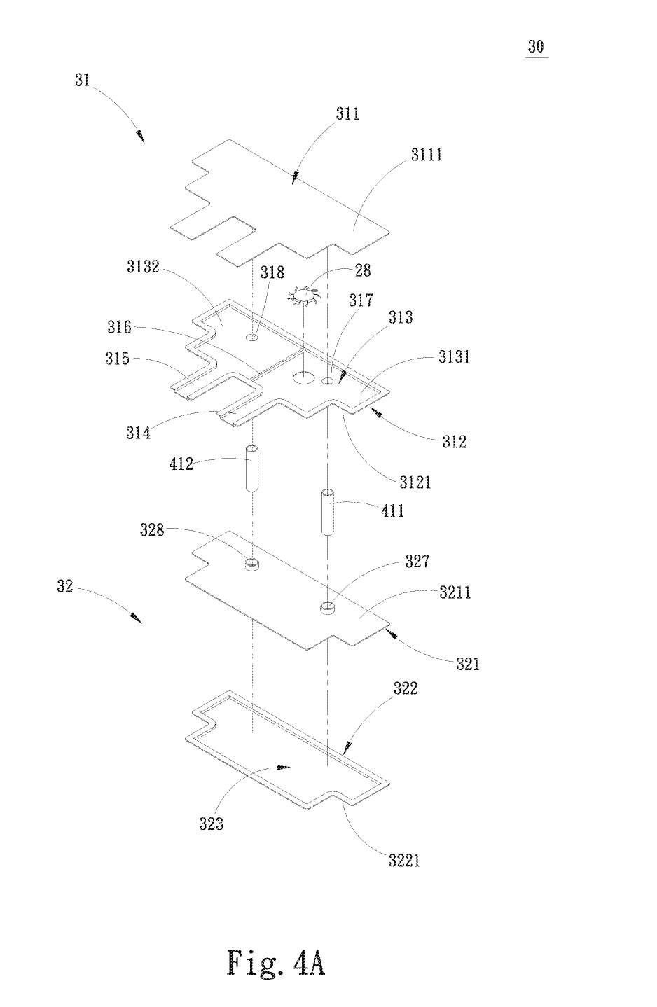

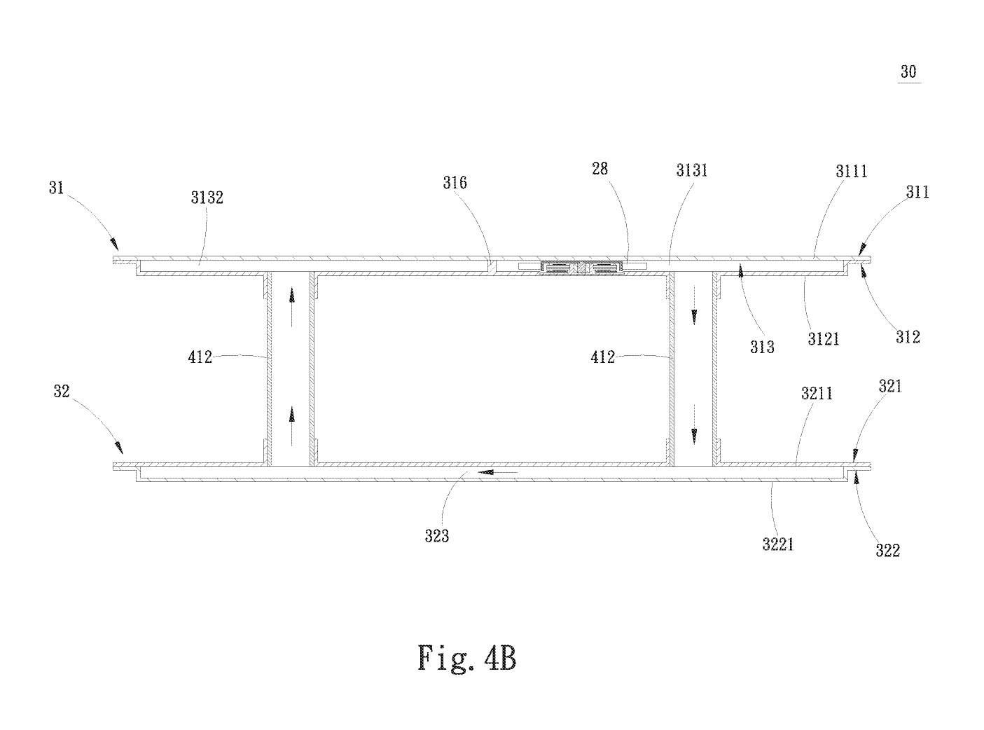

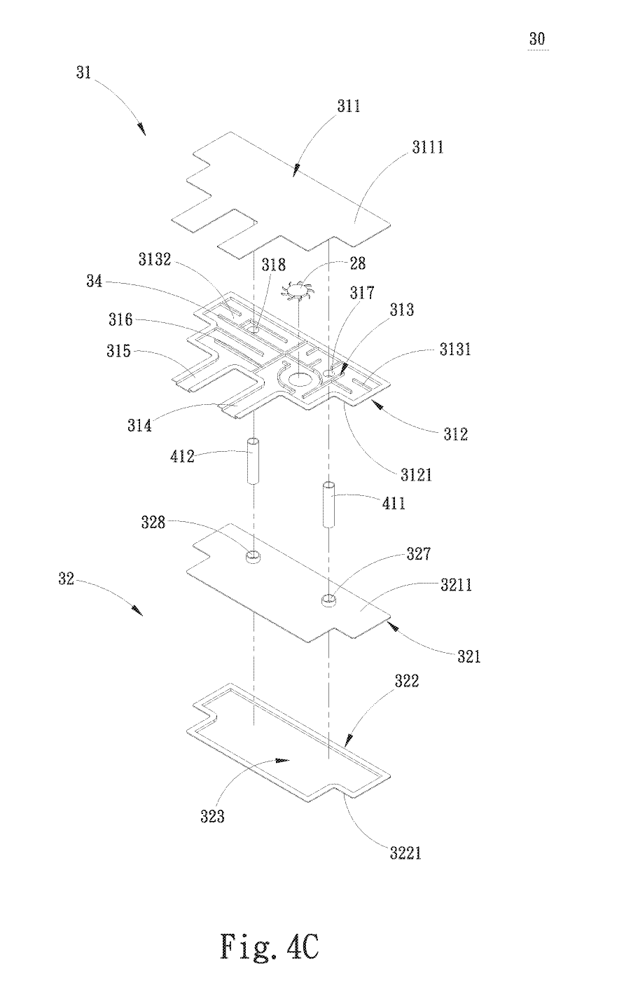

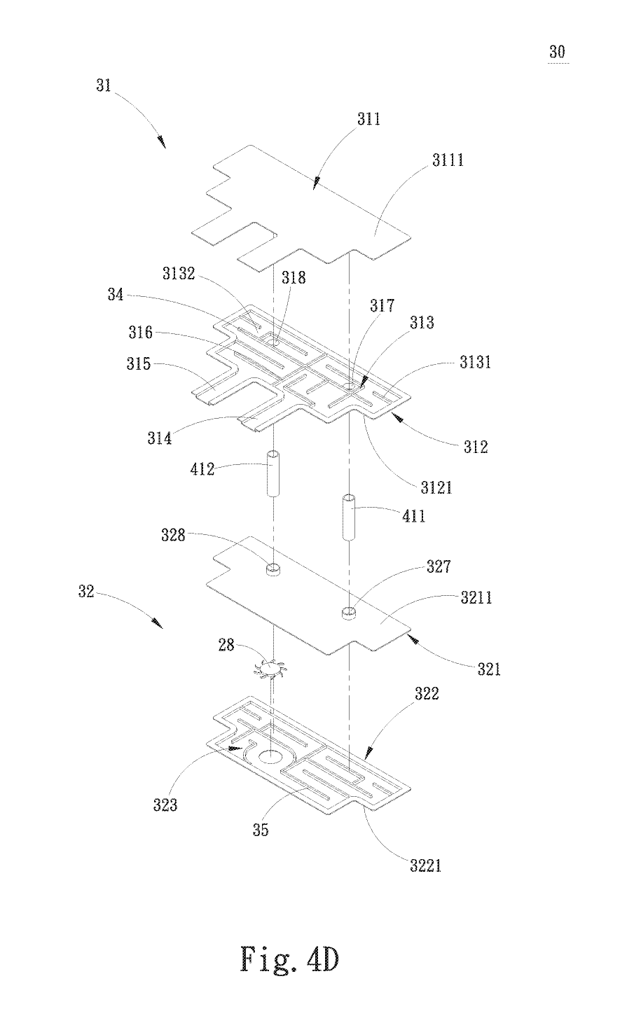

FIGS. 4A and 4B are exploded perspective and assembled sectional views, respectively, of a water-cooling radiator structure according to a second embodiment of the present invention. As shown, in the second embodiment, the water-cooling radiator structure includes a water-cooling radiator unit 30 that includes a water-receiving plate portion consisting of a plurality of water-receiving plates, each of which internally defines a water chamber; and a communicating element portion consisting of a plurality of communicating elements for communicating the water chambers with one another to allow the working fluid to flow through the water chambers via the communicating elements. The water-receiving plates may be stacked in a vertically closely spaced manner or be distributed in a distantly spaced manner, depending on the environment in which the water-receiving plates are to be disposed. While the illustrated second embodiment includes two water-receiving plates, it is understood there is not any particular restriction to the number of the water-receiving plates, which can be increased and fluid communicably connected to one another according to actual need in use and actual condition of usage environment.

In the illustrated second embodiment, the water-cooling radiator unit 30 includes a first water-receiving plate 31 and a second water-receiving plate 32. The first water-receiving plate 31 is formed of a first top plate member 311 and a first bottom plate member 312, such that a first water chamber 313 is defined in between the first top plate member 311 and the first bottom plate member 312. An outer side of the first top plate member 311 is defined as a first upper surface 3111, and an outer side of the first bottom plate member 312 is defined as a first lower surface 3121. The first top and the first bottom plate member 311, 312 are correspondingly provided with two outward extended portions each, such that a water inlet 314 and a water outlet 315 are formed between the extended portions of the first top and bottom plate members 311, 312 when they are closed to each other to form the first water-receiving plate 31. The water inlet 314 and the water outlet 315 are communicable with the first water chamber 313 and a water block unit 91. The second water-receiving plate 32 is formed of a second top plate member 321 and a second bottom plate member 322, such that a second water chamber 323 is defined in between the second top plate member 321 and the second bottom plate member 322. An outer side of the second top plate member 321 is defined as a second upper surface 3211, and an outer side of the second bottom plate member 322 is defined as a second lower surface 3221. In the illustrated second embodiment, the communicating element portion consists of a first communicating element 411 and a second communicating element 412. The first water chamber 313 and the second water chamber 323 are communicable with each other via the first and the second communicating element 411, 412. In the illustrated second embodiment, the first water-receiving plate 31 and the second water-receiving plate 32 are stacked in a vertically spaced manner, such that the second top plate member 321 is correspondingly facing toward the first bottom plate member 312.

In the second embodiment, the first water chamber 313 in the first water-receiving plate 31 is internally provided with a first partitioning rib 316 to divide the first water chamber 313 into a first zone 3131 and a second zone 3132. The first and the second zone 3131 and 3132 are not directly communicable with each other. The first zone 3131 is communicable with the water inlet 314, while the second zone 3132 is communicable with the water outlet 315.

Further, the first water-receiving plate 31 is formed with a first opening 317 and a second opening 318, which are communicable with the first water chamber 313. The first opening 317 and the second opening 318 penetrate the first bottom plate member 312 and are located corresponding to the first zone 3131 and the second zone 3132, respectively. Correspondingly, the second water-receiving plate 32 is formed with a third opening 327 and a fourth opening 328, which penetrate the second top plate member 321 and are communicable with the second water chamber 323. The first communicating element 411 is connected at two opposite ends to the first opening 317 and the third opening 327, so as to communicate the first zone 3131 of the first water chamber 313 with the second water chamber 323. The second communicating element 412 is connected at two opposite ends to the second opening 381 and the fourth opening 328, so as to communicate the second zone 3132 of the first water chamber 313 with the second water chamber 323.

As shown by arrows in FIG. 4B, a working fluid, such as pure water, that has absorbed heat outside the water-cooling radiator unit 30, flows through the water inlet 314 of the first water-receiving plate 31 into the first zone 3131 of the first water chamber 313. Then, the working fluid flows from the first zone 3131 into the second water chamber 323 of the second water-receiving plate 32 via the first communicating element 411. The working fluid keeps flowing from the second water chamber 323 into the second zone 3132 of the first water chamber 313 via the second communicating element 412 and finally leaves the first water-receiving plate 31 via the water outlet 315. When the working fluid flows in through the first water chamber 313, heat absorbed and carried by the working fluid is transferred to the first upper surface 3111 of the first top plate member 311 and to the first lower surface 3121 of the first bottom plate member 312, from where the heat is dissipated into ambient air. When the working fluid flows in through the second water chamber 323, heat absorbed and carried by the working fluid is transferred to the second upper surface 3211 of the second top plate member 321 and to the second lower surface 3221 of the second bottom plate member 322, from where the heat is dissipated into ambient air.

In the second embodiment shown in FIGS. 4A and 4B, the first water chamber 313 and the second water chamber 323 are hollow chambers. However, it is understood the present invention is not necessarily structurally limited to the second embodiment. In a first variant of the second embodiment as shown in FIG. 4C, the first water chamber 313 is internally provided with a first flow passage 34 while the second water chamber 323 is a hollow chamber. Alternatively, in a second variant of the second embodiment as shown in FIG. 4D, the first water chamber 313 and the second water chamber 323 are internally provided with a first flow passage 34 and a second flow passage 35, respectively. These first and second flow passages 34, 35 function as guide paths for the working fluid.

Please refer to FIGS. 4C and 4D. The first flow passage 34 winds and extends in the first water chamber 313, and has two ends separately communicable with the water inlet 314 and the water outlet 315. In FIGS. 4C and 4D, the illustrated first flow passage 34 is formed by providing a plurality of partitioning ribs in the first water chamber 313. However, in an operable embodiment, the first flow passage 34 can be otherwise formed by providing one or a plurality of grooves in the first water chamber 313. The first flow passage 34 and the first water-receiving plate 31 can be two individual members or can be integrally formed with each other. The first flow passage 34 can be connected to or formed on one side of the first top plate member 311 facing toward the first water chamber 313, or be connected to or formed on one side of the first bottom plate member 312 facing toward the first water chamber 313. The first flow passage 34 functions as a guide path for the working fluid, so that the working fluid flowed into the first water chamber 313 keeps flowing along the first flow passage 34.

The second flow passage 35 is similar to the first flow passage 34 but has two ends separately located corresponding to the third opening 327 and the fourth opening 328 on the second top plate member 321 of the second water-receiving plate 32. Whereby, when the working fluid flows into the second water chamber 323 of the second water-receiving plate 32 via the first communicating element 411, the working fluid keeps flowing in the second water chamber 323 along the second flow passage 35 toward the fourth opening 328 and then, flows through the second communicating element 412 into the second zone 3132 of the first water chamber 313. The working fluid finally leaves the first water-receiving plate 31 via the water outlet 315.

Please refer to FIGS. 4A to 4D at the same time. In the second embodiment and the first and second variants thereof, a pump 28 can be optionally arranged inside or outside the first water-receiving plate 31 or the second water-receiving plate 32. In FIGS. 4A to 4C, the illustrated second embodiment and first variant thereof have the pump 28 arranged in the first water chamber 313 of the first water-receiving plate 31. The pump 28 arranged in the first water chamber 313 can be disposed near the water inlet 314 or the water outlet 315. In an operable embodiment, the pump 28 can be disposed at the water inlet 314 or the water outlet 315. The pump 28 can include, for example, an impeller and a driving motor for driving the impeller to rotate and accordingly, drive the working fluid to flow. The driving motor can be, for example, a submersible motor or a waterproof motor. On the other hand, the second variant of the second embodiment shown in FIG. 4D has the pump 28 arranged in the second water chamber 323 of the second water-receiving plate 32.

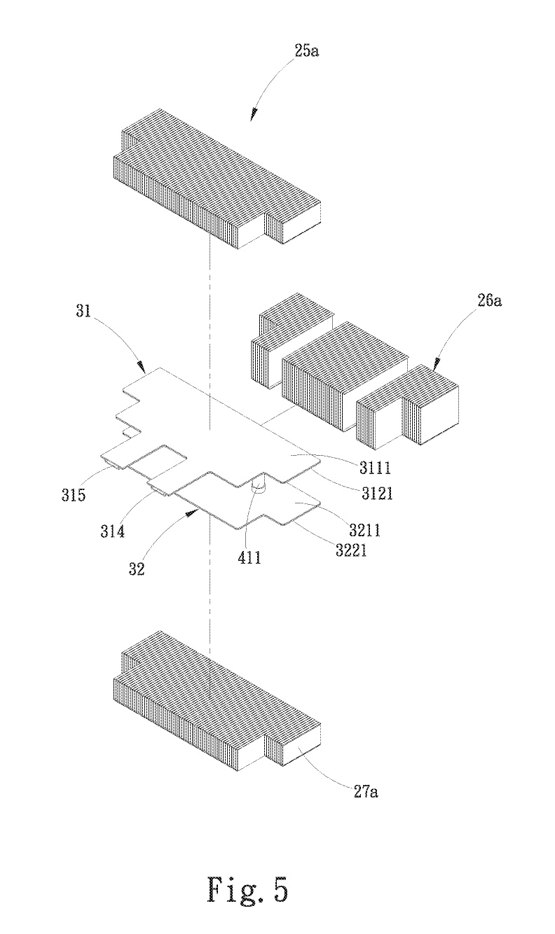

FIG. 5 is an exploded perspective view of a third variant of the second embodiment of the present invention, characterized by including a plurality of radiating fin assemblies. Please refer to FIG. 5 along with FIGS. 4A to 4C. In the third variant of the second embodiment, the water-cooling radiator unit 30 further includes a first radiating fin assembly 25a connected to the first upper surface 3111 of the first water-receiving plate 31, a second radiating fin assembly 26a connected to between the first lower surface 3121 of the first water-receiving plate 31 and the second upper surface 3211 of the second water-receiving plate 32, and a third radiating fin assembly 27a connected to the second lower surface 3221 of the second water-receiving plate 32. The first, the second and the third radiating fin assembly 25a, 26a, 27a respectively include a plurality of radiating fins. Heat transferred to the first upper and lower surfaces 3111, 3121 of the first water-receiving plate 31 and to the second upper and lower surfaces 3211, 3221 of the second water-receiving plate 32 is dissipated into ambient air via the first, the second and the third radiating fin assembly 25a, 26a, 27a.

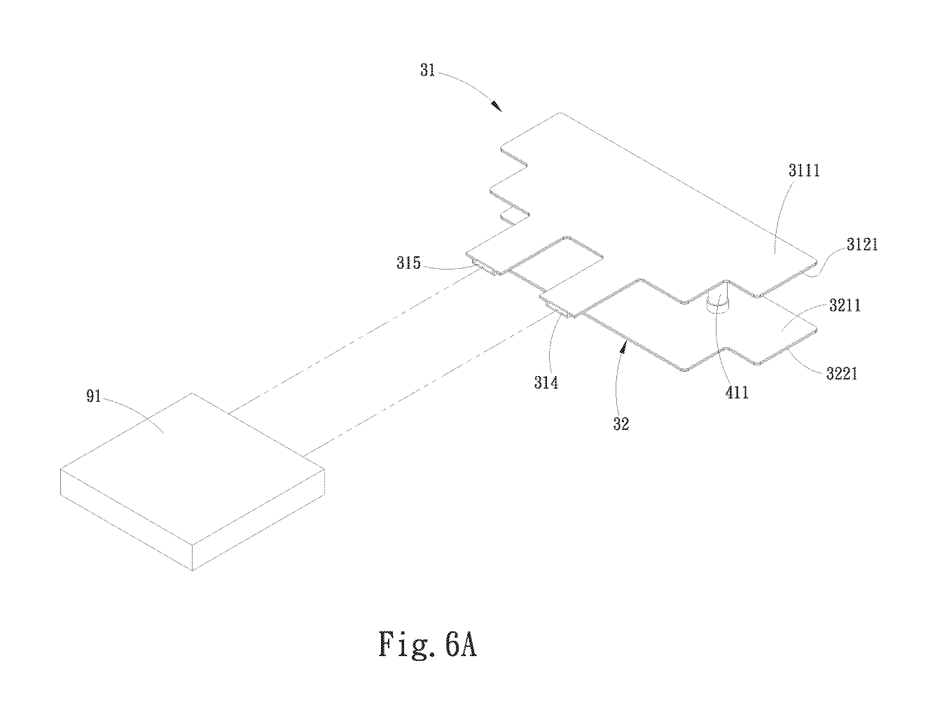

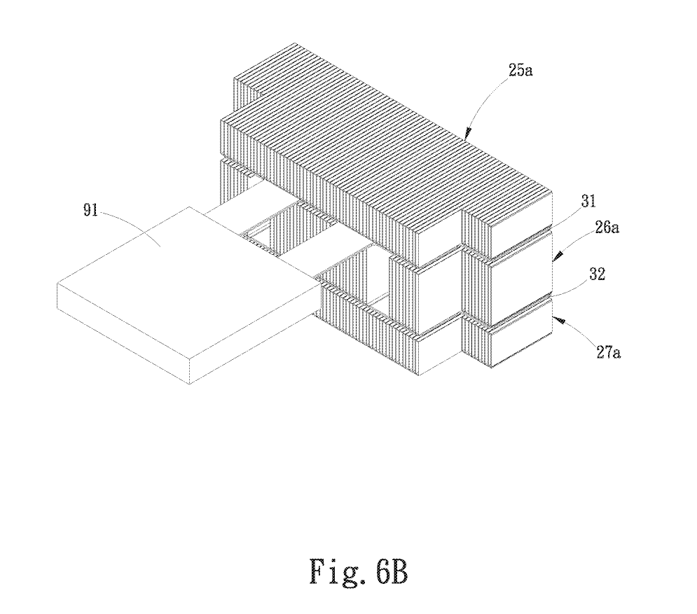

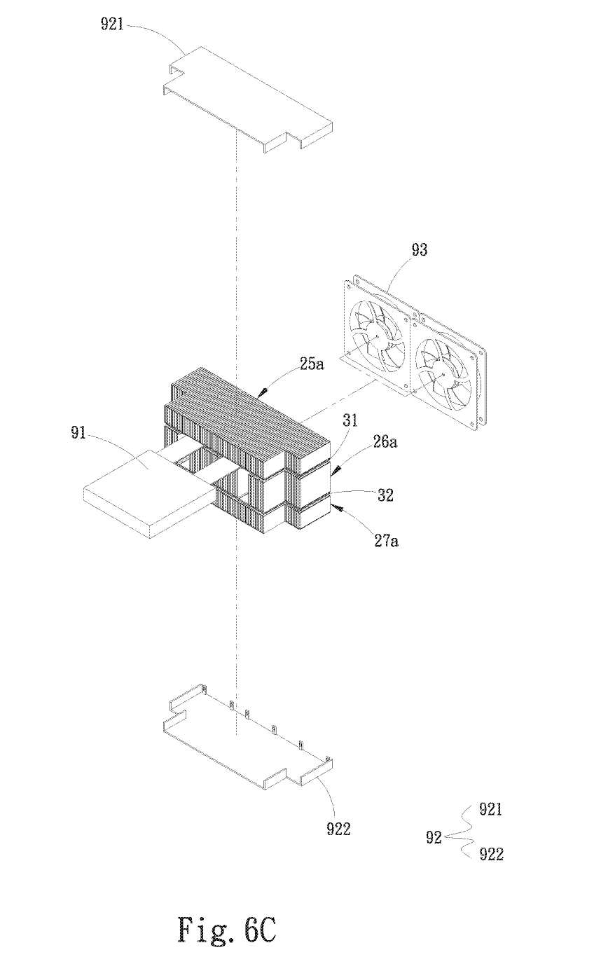

FIG. 6A is an exploded perspective view of a fourth variant of the second embodiment of the present invention, characterized by having a water block unit 91 connected thereto; and FIG. 6B is an assembled perspective view of a fifth variant of the second embodiment of the present invention, which is a combination of the third and the fourth variant and characterized by including a first, a second and a third radiating fin assembly 25a, 26a, 27a and having a water block unit 91 connected thereto. In the fourth and fifth variants of the second embodiment, the water inlet 314 and the water outlet 315 of the first water-receiving plate 31 are connected to the water block unit 91 to communicate the first water chamber 313 with the water block unit 91. The working fluid in the water block unit 91 absorbs heat through heat exchange with a heat-producing element in contact with the water block unit 91, and the heated working fluid flows into the first water chamber 313 of the first water-receiving plate 31 via the water inlet 314, so that heat carried by the working fluid is dissipated into ambient air from the first and second water-receiving plates 31, 32 in the case of the fourth variant, or from the first and second water-receiving plates 31, 32 as well as the first, second, third radiating fin assemblies 25a, 26a, 27a in the case of the fifth variant.

FIG. 6C is an exploded perspective view of a sixth variant of the second embodiment of the present invention, characterized by combining the fifth variant with a protection unit 92 and at least one fan 93. The protection unit 92 is similar to that included in the fourth variant of the first embodiment and includes a first protection part 921 and a second protection part 922, which protectively cover the first, second and third radiating fin assemblies 25a, 26a, 27a as well as the first and second water-receiving plates 31, 32 from a top side and a bottom side of the water-cooling radiator unit 30, protecting the first, second and third radiating fin assemblies 25a, 26a, 27a as well as the first and second water-receiving plates 31, 32 against damages. Further, the at least one fan 93 is optionally connected to the protection unit 92 to helpfully enhance the heat dissipation effect provided by the first, second and third radiating fin assemblies 25a, 26a, 27a and the first and second water-receiving plates 31, 32.

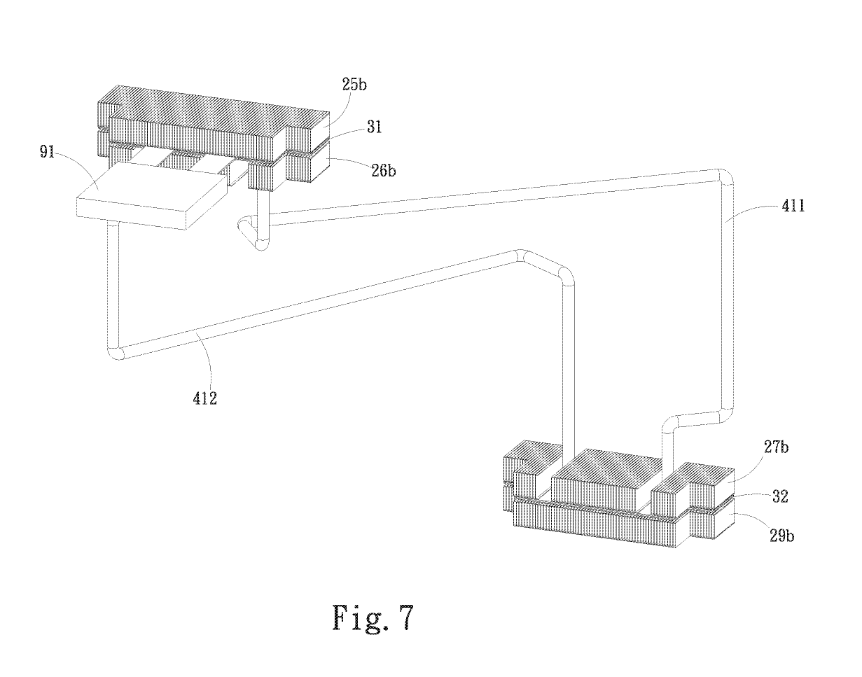

Please refer to FIG. 7, which is an assembled perspective view of a seventh variant of the second embodiment of the present invention, characterized by including a plurality of distantly spaced water-receiving plates. As shown, in the seventh variant, the water-cooling radiator unit 30 includes a first and a second water-receiving plate 31, 32 that are distributed in a distantly spaced manner. That is, the first and the second water-receiving plate 31, 32 are arranged at two different and somewhat distantly spaced positions to meet actual need in use or actual conditions in the usage environment, and are fluid-communicable with each other via the first and the second communicating element 411, 412. Please also refer to FIG. 5 along with FIG. 7. The seventh variant of the second embodiment further includes a first radiating fin assembly 25b connected to the first upper surface 3111 of the first water-receiving plate 31, a second radiating fin assembly 26b connected to the first lower surface 3121 of the first water-receiving plate 31, a third radiating fin assembly 27b connected to the second upper surface 3211 of the second water-receiving plate 32, and a fourth radiating fin assembly 29b connected to the second lower surface 3221 of the second water-receiving plate 32 to helpfully enhance the heat dissipation effect provided by the first and the second water-receiving plate 31, 32.

According to the present invention, the water-receiving plate 21 of the water-cooling radiator unit 20, the first and second water-receiving plates 31, 32 of the water-cooling radiator unit 30, and the first and second communicating elements 411, 412 of the communicating element portion can be made of a gold, a silver, a copper, an iron, a titanium, an aluminum or a stainless steel material, or any alloy thereof. Among others, the titanium material has high metal strength and low weight as well as good heat transfer efficiency to enable effectively upgraded heat dissipation effect and reduced overall weight of the water-cooling radiator structure.

With the above arrangements, the embodiments of the present invention and the variants thereof can provide good heat dissipation performance. Further, the provision of the first and the second flow passage can effectively increase or extend the time for the working fluid to flow in the first and second water chambers, which in turn effectively upgrades the heat dissipation efficiency of the water-cooling radiator structure of the present invention. According to the present invention, when the water-cooling radiator unit includes a plurality of water-receiving plates, such as the first and the second water-receiving plate, these water-receiving plates can be stacked in a vertically closely spaced manner or be distributed in a distantly spaced manner, depending on the usage environment in which the water-cooling radiator unit is arranged.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A water-cooling radiator structure, comprising:
a water-cooling radiator unit including a water-receiving plate internally defining a water chamber for a working fluid to flow therethrough; and the water-receiving plate having an upper surface and a lower surface, from where heat carried by the working fluid flowing through the water chamber is dissipated into ambient air.

2. The water-cooling radiator structure as claimed in claim 1, wherein the water chamber is selected from the group consisting of a hollow water chamber and a water chamber internally provided with a flow passage, and is communicable with a water inlet and a water outlet of the water-receiving plate; and the water inlet and the water outlet being fluid-communicable with a water block unit externally connected thereto.

3. The water-cooling radiator structure as claimed in claim 2, wherein the water chamber is internally provided with a pump for driving the working fluid to flow through the water chamber.

4. The water-cooling radiator structure as claimed in claim 1, wherein the upper surface of the water-receiving plate has a first radiating fin assembly connected thereto.

5. The water-cooling radiator structure as claimed in claim 4, wherein the water-receiving plate is formed of a top plate member and a bottom plate member; an outer side of the top plate member forming the upper surface of the water-receiving plate, and an outer side of the bottom plate member forming the lower surface of the water-receiving plate.

6. The water-cooling radiator structure as claimed in claim 4, wherein the lower surface of the water-receiving plate has a second radiating fin assembly connected thereto.

7. A water-cooling radiator structure, comprising:
a water-cooling radiator unit including:
a water-receiving plate portion consisting of a plurality of water-receiving plates, each of which internally defining a water chamber;
a communicating element portion consisting of a plurality of communicating elements for communicating the water chambers with one another; and
a working fluid flowing from one of the water chambers to another water chamber via the communicating elements.

8. The water-cooling radiator structure as claimed in claim 7, wherein the water-receiving plate portion consists of a first and a second water-receiving plate, and the communicating element portion consists of a first and a second communication element.

9. The water-cooling radiator structure as claimed in claim 8, wherein the first water-receiving plate internally defines a first water chamber for the working fluid to flow therethrough, the second water-receiving plate internally defines a second water chamber for the working fluid to flow therethrough; and the first water chamber and the second water chamber being fluid-communicable with each other via the first and the second communicating element.

10. The water-cooling radiator structure as claimed in claim 9, wherein the first water chamber is selected from the group consisting of a hollow water chamber and a water chamber internally provided with a first flow passage.

11. The water-cooling radiator structure as claimed in claim 10, wherein the second water chamber is selected from the group consisting of a hollow water chamber and a water chamber internally provided with a second flow passage.

12. The water-cooling radiator structure as claimed in claim 9, wherein the first water chamber is fluid-communicable with a water inlet and a water outlet of the first water-receiving plate.

13. The water-cooling radiator structure as claimed in claim 12, wherein the first water chamber is internally provided with a first partitioning rib to divide the first water chamber into a first zone and a second zone; and the first zone and the second zone being fluid-communicable with the water inlet and the water outlet, respectively.

14. The water-cooling radiator structure as claimed in claim 12, wherein the water inlet and the water outlet are fluid-communicable with a water block unit.

15. The water-cooling radiator structure as claimed in claim 9, wherein one of the first and the second water chamber is internally provided with a pump.

16. The water-cooling radiator structure as claimed in claim 9, wherein the first water-receiving plate is formed of a first top plate member and a first bottom plate member that are closed to each other to define the first water chamber in between them, the first top plate member has a first upper surface, and the first bottom plate member has a first lower surface; and wherein the second water-receiving plate is formed of a second top plate member and a second bottom plate member that are closed to each other to define the second water chamber in between them, the second top plate member has a second upper surface, and the second bottom plate member has a second lower surface.

17. The water-cooling radiator structure as claimed in claim 16, further comprising a first radiating fin assembly connected to the first upper surface, a second radiating fin assembly connected to between the first lower surface and the second top surface, and a third radiating fin assembly connected to the second lower surface.

18. The water-cooling radiator structure as claimed in claim 16, further comprising a first radiating fin assembly connected to the first upper surface, a second radiating fin assembly connected to the first lower surface, a third radiating fin assembly connected to the second upper surface, and a fourth radiating fin assembly connected to the second lower surface.

19. The water-cooling radiator structure as claimed in claim 7, wherein the water-receiving plates of the water-receiving plate portion and the communicating elements of the communicating element portion are made of a material selected from the group consisting of gold, silver, copper, iron, titanium, aluminum and stainless steel, and any alloy thereof.

20. The water-cooling radiator structure as claimed in claim 7, wherein the water-receiving plates can be selectively stacked in a vertically closely spaced manner or distributed in a distantly spaced manner.
